(19) United States
(12) Patent Application Publication
(10) Pub. No.: US 2025/0264417 A1
(43) Pub. Date: Aug. 21, 2025

(54) MASK INSPECTION METHOD AND MASK FABRICATING METHOD USING THE SAME

(71) Applicant: Samsung Electronics Co., Ltd., Suwon-si (KR)

(72) Inventor: Yujeong Shin, Suwon-si (KR)

(73) Assignee: Samsung Electronics Co., Ltd., Suwon-si (KR)

(21) Appl. No.: 18/953,772

(22) Filed: Nov. 20, 2024

(30) Foreign Application Priority Data
Feb. 20, 2024 (KR) 10-2024-0024461

(51) Int. Cl. G01N 21/956; G03F 1/36; G03F 7/00

(52) U.S. Cl. CPC G01N 21/956; G03F 1/36; G03F 7/70508; G01N 2021/95676

(57) ABSTRACT

A mask inspection method includes obtaining a plurality of mask layouts corresponding to a mask, each mask layout of the plurality of mask layouts including a plurality of mask patterns, arranging the plurality of mask layouts to overlap each other, determining a margin of an overlapped mask pattern, and determining whether the mask has a defect based on the margin of the overlapped mask pattern.

### CROSS-REFERENCE TO RELATED APPLICATION

This application is based on and claims priority under 35 U.S.C. § 119 to Korean Patent Application No. 10-2024-0024461, filed on Feb. 20, 2024, in the Korean Intellectual Property office, the disclosure of which is incorporated by reference herein in its entirety.

### BACKGROUND

Example embodiments of the disclosure relate to a mask inspection method using a mask pattern and a mask fabricating method including the mask inspection method.

In a semiconductor process, a photolithography process using a mask may be performed to form a pattern on a semiconductor substrate, such as a wafer. The mask may be defined as a pattern transfer body in which a pattern shape of an opaque material is formed on a transparent base material. In an example process of manufacturing the mask, first, a required circuit may be designed and a layout for the required circuit may be designed, and then, mask design data obtained by using an optical probability correction (OPC) process may be transferred as mask tape-out (MTO) design data. Thereafter, a mask data preparation (MDP) process may be performed based on the MTO design data, and an exposure process or the like may be performed to fabricate the mask.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a mask inspection method capable of detecting mask pattern defects and a mask fabricating method including the mask inspection method.

Additional aspects will be set forth in part in the description which follows and, in part, will be apparent from the description, or may be learned by practice of the presented embodiments.

According to an aspect of an example embodiment, a mask inspection method may include obtaining a plurality of mask layouts corresponding to a mask, each mask layout of the plurality of mask layouts including a plurality of mask patterns, arranging the plurality of mask layouts to overlap each other, determining a margin of an overlapped mask pattern, and determining whether the mask has a defect based on the margin of the overlapped mask pattern.

According to an aspect of an example embodiment, a mask inspection method may include obtaining a plurality of mask layouts corresponding to a mask, each mask layout of the plurality of mask layouts including a plurality of mask patterns, arranging the plurality of mask layouts to overlap each other, determining a margin of an overlapped mask pattern, and determining whether the mask has a defect based on the margin of the overlapped mask pattern, where at least two mask layouts among the plurality of mask layouts each may include a mask pattern to be transferred to different vertical levels of a substrate.

According to an aspect of an example embodiment, a mask manufacturing method may include obtaining design layout data as mask tape-out (MTO) design data, preparing mask data based on the MTO design data, inspecting the mask data, and performing an exposure process on a mask substrate based on the mask data, where the inspecting the mask data may include obtaining a plurality of mask layouts corresponding to a mask, each mask layout of the plurality of mask layouts including a plurality of mask patterns, arranging the plurality of mask layouts to overlap each other, determining a margin of an overlapped mask pattern, and determining whether the mask has a defect based on the margin of the overlapped mask pattern.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a flowchart illustrating a mask inspection method according to one or more embodiments;

FIG. 2 is a diagram illustrating an example of overlapping mask patterns according to one or more embodiments;

FIG. 3 is a diagram illustrating an overlapped mask pattern according to one or more embodiments;

FIG. 4 is a flowchart illustrating a mask defect detection method according to one or more embodiments; and

FIG. 5 is a flowchart illustrating a mask manufacturing method including a mask inspection method according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

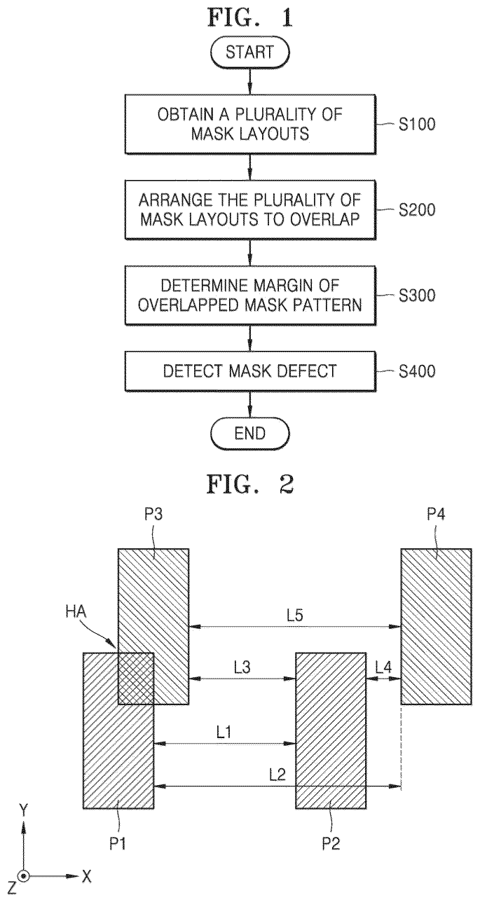

FIG. 1 is a flowchart illustrating a mask inspection method according to one or more embodiments.

As described herein, a mask may include a plurality of mask layouts that are arranged to overlap each other, and each of the plurality of mask layouts may include a plurality of mask patterns. As the plurality of mask layouts are arranged to overlap each other, defects may occur based on the distance between mask patterns and an amount of overlapping between mask patterns, as is described below.

Referring to FIG. 1, a plurality of mask layouts may be obtained in operation S100. For example, the mask layout may include electron-beam (E-Beam) data. For example, the mask layout may include a plurality of mask patterns. The mask pattern may refer to a pattern to be formed on a photolithography mask. In one or more embodiments, a single mask layout may be obtained.

A pattern may be formed on a substrate by transferring a pattern on the mask onto the substrate using an exposure process. In order to form the pattern on the substrate, the mask layout (i.e., a layout of the pattern on the mask corresponding to the pattern on the substrate) may be designed and obtained.

In one or more embodiments, the mask layout may include a mask tape-out (MTO) design layout. The MTO design layout may correspond to the entire mask pattern that may be transferred by using a one-shot scanning process. In general, an extreme ultra-violet (EUV) exposure process may be implemented with a reduced projection (for example, about 4:1 reduced projection). Accordingly, patterns formed on a patterning device, such as a mask pattern, may be reduced to a size of about ¼ and may be transferred to a wafer. In this case, the size reduction of about ¼ may be a reduction ratio of the length, and the area may correspond to the reduction of about 1/16. According to one or more embodiments, the MTO design layout may have a size of about 26 mm in the first horizontal direction (X direction) and a size of about 33 mm in the second horizontal direction (Y direction), but embodiments are not limited thereto.

In one or more embodiments, the mask layout may include a layout in which an optical proximity correction (OPC) process is performed. For example, the mask layout may include the plurality of mask patterns including a hammer head shape and a jog shape. In one or more embodiments, the mask layout may include a layout in which the OPC process has not been performed. For example, the mask layout may include the plurality of mask patterns including a line and space (L/S) shape. The shape of the mask pattern is not limited thereto, and the mask pattern having various shapes may be included.

In operation S100, a plurality of mask layouts each including one or more mask patterns to be transferred to different vertical levels of the substrate may be obtained.

In operation S200, the plurality of mask layouts may be arranged to overlap each other. In this case, the plurality of mask layouts being arranged to overlap each other may refer to a process in which the plurality of mask layouts including the mask patterns to be transferred to different vertical levels of the substrate overlap each other. In other words, the plurality of mask patterns to be transferred to different vertical levels of the substrate may overlap each other. Accordingly, the plurality of mask layouts may be arranged to overlap each other on one horizontal flat surface. In other words, the plurality of mask patterns to be transferred to different vertical levels of the substrate may be arranged to overlap each other on one horizontal flat surface.

In one or more embodiments, a direction in parallel with a main surface of the mask layout may be defined as a horizontal direction (X direction and/or Y direction), and a direction perpendicular to the horizontal direction (X direction and/or Y direction) may be defined as the vertical direction (Z direction).

Thereafter, a margin of overlapped mask patterns of the plurality of mask layouts may be determined in operation S300. The margin may include a first margin and a second margin. The first margin may include a margin between each of the plurality of mask patterns to be transferred to the same vertical level of the substrate. For example, the first margin may include a margin between each of a plurality of mask patterns of a single mask layout. For example, the first margin may include a bridge margin and a pinch-off margin.

The bridge margin may refer to a horizontal separation distance between mask patterns that are spaced apart from each other in the horizontal direction (X direction and/or Y direction). For example, the bridge margin may refer to a horizontal direction (X direction and/or Y direction) separation distance between different mask patterns. For example, the bridge margin may be determined in units of about 0.1 nm. However, embodiments are not limited thereto, and the bridge margin may be modified and determined in various units.

The pinch-off margin may include a margin indicating a pinch-off defect caused by a patterning failure. The pinch-off margin may refer to a horizontal separation distance of different mask patterns. For example, the pinch-off margin may refer to the horizontal direction (X direction and/or Y direction) separation distance between different mask patterns. For example, the pinch-off margin may be determined in units of about 0.1 nm. However, embodiments are not limited thereto, and the pinch-off margin may be modified and determined in various units.

The second margin may include a margin between each of the plurality of mask patterns of different mask layouts. In other words, the second margin may include a margin between each of the plurality of mask patterns to be transferred to different vertical levels of the substrate. For example, the second margin may include a short margin and an overlap margin.

The short margin may refer to a horizontal separation distance between mask patterns spaced apart from each other. For example, the short margin may refer to a horizontal separation distance between mask patterns that are spaced apart from each other in the horizontal direction (X direction and/or Y direction). For example, the short margin may refer to a horizontal direction (X direction and/or Y direction) separation distance between different mask patterns. For example, the short margin may be determined in units of about 0.1 nm. However, embodiments are not limited thereto, and the short margin may be modified and determined in various units.

The overlap margin may refer to an overlapped area between mask patterns overlapping in the vertical direction (Z direction). For example, the overlap margin may refer to a horizontal area of the overlapped area of the plurality of mask patterns.

By performing operation S300, a spatial margin of the plurality of mask patterns to be transferred to the same vertical level of the substrate and/or a margin of the plurality of mask patterns to be transferred to different vertical levels of the substrate may be determined. Accordingly, the quantity/defect of the plurality of mask patterns to be transferred to the same vertical level of the substrate and/or a plurality of mask patterns to be transferred to different vertical levels of the substrate may be measured. For example, when the mask patterns spaced apart from each other overlap each other, the mask layout may be determined as defective. To the contrary, when the mask patterns overlapping in the vertical direction (Z direction) are spaced apart from each other in the horizontal direction (X direction and/or Y direction), the mask layout may also be determined as defective.

In this case, the plurality of mask patterns to be transferred to different vertical levels of the substrate may overlap each other. In other words, ]the mask patterns to be transferred to layers adjacent to each other in the vertical direction (Z direction) of the substrate, and the plurality of mask patterns to be transferred to layers not adjacent to each other in the vertical direction (Z direction) of the substrate may overlap each other.

Thereafter, a defect in the mask may be detected in operation S400. A defect in the mask may include a defect in the mask layout or the mask pattern. A defect in the mask pattern may be detected based on a margin of the overlapped mask patterns. For example, a defect in the mask pattern may include a short defect and/or an overlap defect. The short defect and/or the overlap defect may include a defect that occurs in the plurality of mask patterns to be transferred to different vertical levels of the substrate. In other words, the short defect and/or the overlap defect may include a defect that occurs between each of the plurality of mask patterns of different mask layouts.

For example, the short defect may include a defect that occurs when patterns to be electrically separated from each other are electrically connected to each other. The overlap defect may include a defect that occurs due to more and/or less patterns overlapping each other than designed. Whether the short defect occurs may be detected based on the short margin, and whether the overlap defect occurs may be detected based on the overlap margin.

When the short margin of the overlapped mask pattern is less than a reference value, the short defect may be detected. When the difference between the overlap margin of the overlapped mask pattern and the reference value is large, the overlap defect may be detected.

The reference value used to detect the short defect may be referred to as a first reference value, and the reference value used to detect the overlap defect may be referred to as a second reference value. In addition, the mask patterns spaced apart from each other (for example, short defect inspection object mask patterns) may be referred to as first target patterns, and the mask patterns overlapping each other (for example, overlap defect inspection object mask pattern) may be referred to as second target patterns.

When the short defect of the mask pattern is detected, the short margin of the first target pattern may be compared with the first reference value. When the short margin of the first target pattern is less than or equal to the first reference value, the first target pattern may be identified as including the short defect. When the short margin of the first target pattern is greater than the first reference value, the first target pattern may be identified as not including the short defect.

When the overlap defect of the mask pattern is detected, the overlap margin of the second target pattern may be compared with the second reference value. When the overlap margin of the second target pattern is outside the range of the second reference value, the second target pattern may be identified as including the overlap defect.

For example, a defect in the mask pattern may include a bridge defect and/or a pinch-off defect. The bridge defect and/or the pinch-off defect may be a defect that occurs in the plurality of mask patterns to be transferred to the same vertical level of the substrate. In other words, the bridge defect and/or the pinch-off defect may include a defect that occurs between each of the plurality of mask patterns of the single mask layout.

For example, the bridge defect may occur when patterns spaced apart from each other are connected to each other. The pinch-off defect may not be patterned due to poor patterning, and/or may occur when the patterning is not completed and/or a thickness of the pattern is less than a design value. Whether the bridge defect occurs may be detected based on the bridge margin, and whether the pinch-off defect occurs may be detected based on the pinch-off margin.

When the bridge margin of the mask pattern is less than a reference value, the bridge defect may be detected. Similarly, when the pinch-off margin of the mask pattern is greater than a reference value, the pinch-off defect may be detected.

A reference value used to detect the bridge defect may be referred to as a third reference value, and a reference value used to detect the pinch-off defect may be referred to as a fourth reference value. In addition, the mask patterns spaced apart from each other (for example, bridge defect inspection object mask patterns) may be referred to as third target patterns, and the mask patterns connected to each other (for example, pinch-off defect inspection object mask pattern) may be referred to as fourth target patterns.

In other words, when the bridge defect of the mask pattern is detected, the bridge margin of the third target pattern may be compared with the third reference value. When the bridge margin of the third target pattern is equal to or less than the third reference value, the third target pattern may be identified as including the bridge defect. When the bridge margin of the third target pattern is greater than the third reference value, the third target pattern may be identified as not including the bridge defect.

When the pinch-off defect of the mask pattern is detected, the pinch-off defect of the fourth target pattern may be compared with the fourth reference value. When the pinch-off margin of the fourth target pattern is equal to or less than the fourth reference value, the fourth target pattern may be identified as not including the pinch-off defect. When the pinch-off margin of the fourth target pattern is greater than the fourth reference value, the fourth target pattern may be identified as including the pinch-off defect.

The mask inspection method according to one or more embodiments may detect defects in the plurality of mask layouts to be transferred to different vertical levels of the substrate. The mask inspection method according to one or more embodiments may perform an inspection on the mask layout, by determining a margin by overlapping the plurality of mask layouts to be transferred to different vertical levels of a substrate. Accordingly, the mask inspection method according to one or more embodiments may provide a method for inspecting a mask with high reliability.

In addition, the mask inspection method according to one or more embodiments may inspect a mask in a non-destructive manner. Thus, the mask inspection method according to one or more embodiments may provide a method for inspecting a mask with high reliability.

FIG. 2 is a diagram illustrating examples of overlapping mask patterns according to one or more embodiments. FIG. 2 illustrates, as an example, that the mask patterns to be transferred to different vertical levels of the substrate are overlapped.

In FIG. 2, a pattern having the same hatching may be transferred to the same vertical level of the substrate. For example, a first pattern P1 and a second pattern P2 may be transferred to the same vertical level of the substrate, and a third pattern P3 and a fourth pattern P4 may be transferred to the same vertical level of the substrate.

FIG. 2 illustrates a case in which the mask pattern has the L/S shape. However, embodiments are not limited thereto, and the mask pattern may have various shapes. For example, the mask pattern may have a hammer head and a jog shape.

In addition, although FIG. 2 illustrates that the first margin and the second margin are determined by considering only the distances at which the first through fourth patterns P1 through P4 are spaced apart from each other in the first horizontal direction (X direction), embodiments are not limited thereto. The first margin and the second margin may be measured considering the distances at which the first through fourth patterns P1 through P4 are spaced apart from each other in the second horizontal direction (Y direction) and/or the diagonal direction.

Referring to FIG. 2, a plurality of mask layouts may overlap each other, and the first through fourth patterns P1 through P4 may be on the same plane. At least a portion of the first pattern P1 and at least a portion of the third pattern P3 may overlap each other. In other words, at least a portion of the first pattern P1 and at least a portion of the third pattern P3 that are to be spaced apart from each other and transferred in the vertical direction (Z direction) from the substrate may overlap each other in the vertical direction (Z direction).

When the mask patterns from different mask layouts overlap each other, the overlap margin may be measured. The overlap margin may be measured based on a horizontal area of an overlapped area HA.

The first horizontal direction (X direction) separation distance between the first pattern P1 and the second pattern P2 may be referred to as a first distance L1. Because the first pattern P1 and the second pattern P2 include mask patterns formed in the same mask layout, the first distance L1 may be the first margin. For example, the first distance L1 may include the bridge margin. In one or more embodiments, the first distance L1 may include the pinch-off margin. The first horizontal direction (X direction) separation distance between the first pattern P1 and the fourth pattern P4 may be referred to as a second distance L2. Because the first pattern P1 and the fourth pattern P4 include mask patterns formed in different mask layouts, the second distance L2 may include the second margin. For example, the second distance L2 may include the short margin.

The second pattern P2 and the third pattern P3 may be spaced apart from each other by a third distance L3 in the first horizontal direction (X direction), and the second pattern P2 and the fourth pattern P4 may be spaced apart from each other by a fourth distance L4 in the first horizontal direction (X direction). As described above, the third distance L3 and the fourth distance L4 may include the second margin. For example, the third distance L3 and the fourth distance L4 may include the short margin. The third pattern P3 and the fourth pattern P4 may be spaced apart from each other by a fifth distance L5 in the first horizontal direction (X direction), and because the third pattern P3 and the fourth pattern P4 include the mask patterns formed in the same mask layout, the fifth distance L5 may include the first margin. For example, the fifth distance L5 may include the bridge margin. In one or more embodiments, the fifth distance L5 may include the pinch-off margin.

The overlapped area HA and the first through fifth distances L1 through L5 may be measured, based on the position and size of each of the first through fourth patterns P1 through P4. Thereafter, by comparing the overlapped area HA and each of the first through fifth distances L1 through L5 with a reference value, the mask inspection may be performed.

In other words, the mask inspection method may provide an inspection method of the plurality of mask patterns of the same mask layout, and in addition, may also provide an inspection method of the plurality of mask patterns of different mask layouts. In other words, the mask inspection method may provide an inspection method of a plurality of mask patterns to be transferred to the same vertical level of the substrate, and may provide an inspection method of the plurality of mask patterns to be transferred to different vertical levels of the substrate. The mask inspection method may provide an inspection method of a mask based on margins of a plurality of overlapped mask patterns.

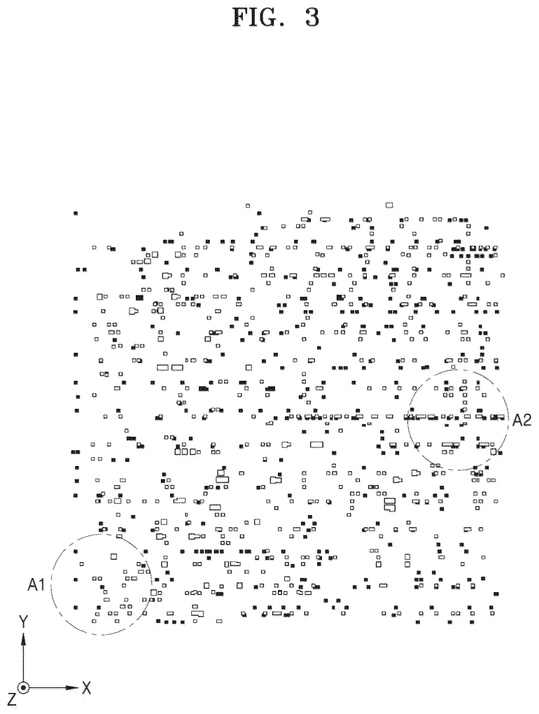

FIG. 3 is a diagram illustrating an overlapped mask pattern according to one or more embodiments. FIG. 3 illustrates, as an example, that the mask patterns to be transferred to different vertical levels of the substrate are overlapped. In FIG. 3, each of black color patterns and white color patterns may include a mask pattern to be transferred to different vertical levels of the substrate. Descriptions are given with reference to FIG. 2 together.

Referring to FIG. 3, the plurality of mask patterns to be transferred to a plurality of vertical levels of a substrate are illustrated. In one or more embodiments, the bridge margin, the pinch-off margin, the overlap margin, and/or the short margin of an overlapped mask pattern may be determined.

In addition, the margins between the mask patterns to be transferred to adjacent layers in the vertical direction (Z direction) of the substrate may be determined. In other words, at least some of the layers may be selected from among a plurality of layers, and the spatial margin of the plurality of patterns inside the selected layer may be determined. In one or more embodiments, the margins between the mask patterns to be transferred to layers apart from each other in the vertical direction (Z direction) of the substrate may be determined.

For example, a first area A1 in FIG. 3 may include an area in which mask patterns of different mask layouts are spaced apart from each other in horizontal directions (X and/or Y directions). A second area A2 may include an area having mask patterns of different mask layouts overlapping each other.

Accordingly, the short margin between the overlapped mask patterns may be measured in the first area A1, and the overlap margin between the overlapped mask patterns may be measured in the second area A2. When the short margin of the mask patterns in the first area A1 is greater than the reference value, the mask patterns in the first area A1 may be determined as normal, and when the overlap margin of the mask patterns in the second area A2 is within the reference value, the mask patterns in the second area A2 may be determined as normal. When the short margin of the mask patterns in the first area A1 is less than the reference value, the mask patterns in the first area A1 may be determined as defective, and when the overlap margin of the mask patterns in the second area A2 is greater than the reference value, the mask patterns in the second area A2 may be determined as defective.

In FIGS. 2 and 3, an inspection method of a mask by using two different overlapped mask layouts is described, but embodiments are not limited thereto. For example, three or more mask layouts may overlap each other.

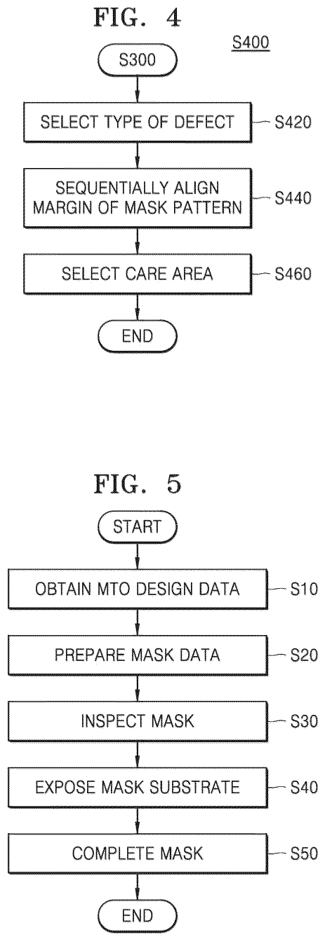

FIG. 4 is a flowchart illustrating a mask defect detection method according to one or more embodiments. FIG. 4 is described with reference to FIGS. 1 and 3 together.

Referring to FIG. 4, in operation S400 of detecting a mask defect, a type of defect to be detected may be first selected in operation S420. In one or more embodiments, the mask defect may include the short defect and the overlap defect. As described above, the short defect may be referred to as a defect in which patterns that needs not be electrically connected to each other contact each other and are electrically connected to each other. The overlap defect may be referred to as a defect in which patterns to be electrically connected to each other are spaced apart from each other, or an overlapped area of the patterns is different from the design pattern.

In one or more embodiments, the mask defect may include the bridge defect and the pinch-off defect. As described above, the bridge defect may be referred to as a defect in which patterns to be spaced apart from each other are connected to each other, and the pinch-off defect may be referred to as a defect generated when the patterning is not properly completed and/or the level of patterning is poor such that the thickness of the pattern is less than the design value.

In operation S440, the margins of the mask pattern may be sequentially aligned, based on the type of the defect selected in operation S420. As described above, the margin may include the first margin and the second margin. The first margin may refer to a margin between mask patterns of the single mask layout. In other words, the first margin may include the bridge margin and the pinch-off margin. In addition, the second margin may refer to a margin between the mask patterns of the different mask layouts. For example, the second margin may include the short margin and the overlap margin.

For example, when determining whether the short defect has occurred, the short margins of the target patterns may be arranged in an ascending order. For example, when determining whether the overlap defect has occurred, the overlap margins may be aligned in order of difference from the reference value. In other words, the differences between the overlap margins and the reference value of the target patterns may be arranged in a descending order.

For example, when determining whether the bridge defect has occurred, the bridge margins of the target patterns may be arranged in an ascending order. When determining whether the pinch-off defect of the target pattern has occurred, the pinch-off margins of the target patterns may be arranged in a descending order.

Thereafter, at least a portion of the overlapped mask layout may be selected as a care area in operation S460. Because the margins of the overlapped mask patterns are sequentially aligned in operation S440, the care area including at least a portion of the overlapped mask pattern may be selected. In one or more embodiments, as the aligned order decreases, the priority of the mask pattern may increase.

For example, when determining whether the short defect has occurred, as the short margins of the mask patterns decrease, the inspection priority of an area including the mask pattern may increase. In addition, when determining whether the overlap defect has occurred, as differences between the overlap margins of the mask patterns and the reference value increase, the inspection priority of an area including the mask patterns may increase.

For example, when determining whether the bridge defect has occurred, as the spatial margins of the mask patterns decrease, the inspection priority of an area including the mask patterns may increase. When determining whether the pinch-off defect has occurred, as the spatial margins of the mask patterns increase, the inspection priority of an area including the mask patterns may increase.

In one or more embodiments, an area including a mask pattern having a high inspection priority may be selected as the care area. In other words, the care area may be selected based on the inspection priority.

For example, the first area A1 and the second area A2 in FIG. 3 may be compared. The short margin of the mask pattern arranged in the first area A1 may be less than the short margin of the mask pattern arranged in the second area A2. As described above, when determining whether the short defect has occurred, as the short margin between mask patterns to be transferred to different vertical levels decreases, the priority of the mask pattern may increase. Accordingly, the second area A2 may have a higher inspection priority than the first area A1.

The mask defect detection method according to one or more embodiments may include an operation of sequentially aligning margins of mask patterns. Accordingly, the mask defect detection method according to one or more embodiments may provide a method of inspecting whether a defect of a mask pattern has occurred by considering at least some of a plurality of mask patterns. Thus, the speed of mask defect detection increases, the reliability of the mask defect detection may be improved, and the turn-around time (TAT) of the mask defect detection may be reduced.

FIG. 5 is a flowchart illustrating a mask manufacturing method including a mask inspection method according to one or more embodiments. FIG. 5 is described with reference to FIGS. 1 through 4.

Referring to FIG. 5 MTO design data may be obtained in operation S10. In this case, the MTO design data may include a design layout on which the OPC has been performed. In one or more embodiments, the MTO design data may include a design layout on which the OPC has not been performed.

The design layout may include various geometric patterns for implementing a semiconductor device to be implemented. Patterns of the design layout may include various geometric patterns including line patterns having a certain width and extending horizontally and curved patterns including curved edges. Various geometric patterns of the design layout may correspond to metal patterns, oxide patterns, or semiconductor patterns implemented on a substrate (for example, a semiconductor wafer) to manufacture various components of a semiconductor device. The components may include, for example, active areas, gate electrodes, vias of metal lines or interlayer interconnections, bonding pads, etc. The components may be formed on a semiconductor substrate, or various material layers deposited on the semiconductor substrate.

In general, the MTO may refer to a task of transferring data of the final design layout to a mask manufacturing team and requesting for manufacturing the mask. Accordingly, in the mask manufacturing method according to one or more embodiments, such pieces of MTO design data may have a graphic data format used in electronic design automation (EDA) software, etc. For example, the MTO design data may have a data format, such as a graphic data system II (GDS2) and an open artwork system interchange standard (OASIS).

Next, mask data preparation (MDP) may be performed in operation S20. The MDP may include, for example, a format conversion known as fracturing, an augmentation of a bar code for mechanical reading, a standard mask pattern for inspection, and a job deck, or the like, and verification of automatic and manual methods. In this case, the job deck may refer to an operation of generating a text file related to a series of commands, such as arrangement information about multi-mask files, reference dose, exposure speed, and exposure method.

The format conversion (that is, fracturing) may refer to a process of dividing the MTO design data into respective areas and changing the MTO design data into a format for an electron beam writer. The fracturing may include, for example, data manipulation, such as scaling, sizing of data, rotation of data, pattern reflection, and color reversal. In a conversion process by using the fracturing, data for various systematic errors occurring somewhere in a process of transferring the design data to an image on a wafer may be corrected.

A data compensation process on the systematic errors may be referred to as a mask process correction (MPC), and may include, for example, line width adjustment referred to as critical dimension (CD) adjustment, an operation of increasing a pattern arrangement accuracy, etc. Thus, the fracturing may be a process which contributes to improve quality of the final mask, and in addition, may be performed in advance for the mask process correction. In this case, the systematic errors may be caused by distortion occurring in the exposure process, a mask development process, a mask etching process, a wafer imaging process, etc.

On the other hand, the MDP may include the MPC. The MPC may be referred to as a process of correcting an error occurring during the exposure process as described above (that is, a process of correcting the systematic error). In this case, the exposure process may include a concept generally including electron beam writing, developing, etching, bake, etc. In addition, data processing may be performed ahead of the exposure process. The data processing may include a kind of a pre-processing process for mask data, and may include grammar checking, exposure time prediction, or the like of the mask data.

Thereafter, a mask inspection may be performed in operation S30. Operation S30 of inspecting the mask may include operations S100-S400 of FIG. 1.

After the mask is inspected, a mask substrate may be exposed based on the mask data in operation S40. In this case, the exposure may refer to, for example, the electron beam writing. In this case, the electron beam writing may be performed by using a gray writing method using, for example, a multi-beam mask writer (MBMW). In addition, the electron beam writing may also be performed by using a variable shape beam (VSB) writer.

On the other hand, after the MDP is completed, a process of converting the mask data into pixel data may be performed prior to the exposure process. The pixel data may include data that is directly used for an actual exposure, and may include data on shapes of an object to be exposed and data on a dose allocated to each shape of the object. In this case, the data on shapes may include bit-map data into which shape data, or vector data, has been converted by rasterization, etc.

After the exposure process, a series of processes may be performed to complete the mask in operation S50. The series of processes may include processes of, for example, development, etching, cleaning, etc. In addition, the series of processes of manufacturing a mask may include a measurement process, a defect inspection, and a defect repair process. Furthermore, a series of processes of manufacturing a mask may also include a pellicle application process. In this case, when it is verified by final cleaning and inspection processes that there are no contamination particles or chemical stains, the pellicle application process may be performed, and the pellicle application process may refer to a process of attaching the pellicles to a mask surface to protect the mask from subsequent contamination during a delivery and a service life of the mask.

In the mask manufacturing method according to one or more embodiments, the mask inspection method may include an operation of overlapping mask layouts including mask patterns to be transferred to different vertical levels of the substrate. Accordingly, the mask manufacturing method according to one or more embodiments may check whether a mask pattern to be transferred to different vertical levels of the substrate is defective. Thus, the mask manufacturing method according to one or more embodiments may inspect the mask with high reliability.

In addition, in the mask manufacturing method according to one or more embodiments, an inspection method of a mask in a non-destructive manner may be provided. Therefore, the mask manufacturing method according to according to one or more embodiments may inspect the mask with high reliability.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A mask inspection method comprising:
obtaining a plurality of mask layouts corresponding to a mask, each mask layout of the plurality of mask layouts comprising a plurality of mask patterns;
arranging the plurality of mask layouts to overlap each other;
determining a margin of an overlapped mask pattern; and
determining whether the mask has a defect based on the margin of the overlapped mask pattern.

2. The mask inspection method of claim 1, wherein the determining of the margin of the overlapped mask pattern is performed based on at least one of a horizontal separation distance of the overlapped mask pattern, and an overlapped horizontal area of the overlapped mask pattern.

3. The mask inspection method of claim 1, wherein the determining of the margin of the overlapped mask pattern is performed based on at least one of a short margin determined based on a horizontal separation distance of the overlapped mask pattern; and an overlap margin determined based on a horizontal area of the overlapped mask pattern.

4. The mask inspection method of claim 3, wherein the determining whether the mask has a defect comprises:
determining that the overlapped mask pattern is defective based on the short margin of the overlapped mask pattern being a first reference value or less; and
determining that the overlapped mask pattern is not detective based on the short margin of the overlapped mask pattern being greater than the first reference value.

5. The mask inspection method of claim 3, wherein the determining whether the mask has a defect comprises:
determining that the overlapped mask pattern is defective, based on the overlap margin of the overlapped mask pattern being outside a range of a second reference value; and
determining that the overlapped mask pattern is not defective, based on the overlap margin of the overlapped mask pattern being within the range of the second reference value.

6. The mask inspection method of claim 1, wherein the plurality of mask layouts are configured to be transferred to layers adjacent to each other in a vertical direction of a substrate.

7. The mask inspection method of claim 1, wherein the plurality of mask layouts are configured to be transferred to layers spaced apart from each other in a vertical direction of a substrate.

8. A mask inspection method comprising:
obtaining a plurality of mask layouts corresponding to a mask, each mask layout of the plurality of mask layouts comprising a plurality of mask patterns;
arranging the plurality of mask layouts to overlap each other;
determining a margin of an overlapped mask pattern; and
determining whether the mask has a defect based on the margin of the overlapped mask pattern,
wherein at least two mask layouts among the plurality of mask layouts each comprises a mask pattern to be transferred to different vertical levels of a substrate.

9. The mask inspection method of claim 8, wherein the determining the margin of the overlapped mask pattern comprises:
determining a margin between mask patterns to be transferred to a same vertical level of the substrate; and
determining a margin between the mask patterns of the at least two mask layouts to be transferred to different vertical levels of the substrate.

10. The mask inspection method of claim 8, wherein the determining the margin of the overlapped mask pattern comprises:
determining at least one of a first margin comprising at least one of a bridge margin and a pinch-off margin; and
a second margin comprising at least one of a short margin and an overlap margin.

11. The mask inspection method of claim 8, wherein the determining whether the mask has a defect comprises: selecting a type of defect; and
selecting a care area.

12. The mask inspection method of claim 11, wherein the type of defect comprises at least one of a short defect, an overlap defect, a bridge defect, and a pinch-off defect.

13. The mask inspection method of claim 11, further comprising:
increasing a priority of a first mask pattern based on the type of defect being at least one of a short defect and a bridge defect, and as a margin of the first mask pattern decreases; and increasing a priority of a second mask pattern based on the type of defect being a pinch-off defect, and as a margin of the second mask pattern increases.

14. The mask inspection method of claim 11, further comprising:
increasing a priority of a third mask pattern based on the type of defect being an overlap defect, and as a difference between a margin of the third mask pattern from a reference value increases.

15. The mask inspection method of claim 11, wherein the selecting the care area is performed based on a priority of a mask pattern.

16. A mask manufacturing method comprising:
obtaining design layout data as mask tape-out (MTO) design data;
preparing mask data based on the MTO design data;
inspecting the mask data; and
performing an exposure process on a mask substrate based on the mask data,
wherein the inspecting the mask data comprises:
obtaining a plurality of mask layouts corresponding to a mask, each mask layout of the plurality of mask layouts comprising a plurality of mask patterns;
arranging the plurality of mask layouts to overlap each other;
determining a margin of an overlapped mask pattern; and
determining whether the mask has a defect based on the margin of the overlapped mask pattern.

17. The mask manufacturing method of claim 16, wherein at least two mask layouts among the plurality of mask layouts each comprises a mask pattern to be transferred to different vertical levels of a substrate.

18. The mask manufacturing method of claim 16, wherein the determining whether the mask has a defect is performed based on at least one of a bridge margin, a pinch-off margin, a short margin, and an overlap margin.

19. The mask manufacturing method of claim 16, wherein the determining whether the mask has a defect comprises:
selecting a type of defect; and
selecting a care area,
wherein, as an alignment priority decreases, a priority of a first mask pattern increases.

20. The mask manufacturing method of claim 19, further comprising:
increasing the priority of the first mask pattern based on the type of defect being at least one of a short defect and a bridge defect, and as a margin of the first mask pattern decreases;
increasing the priority of the first mask pattern based on the type of defect being pinch-off defect, and as the margin of the first mask pattern increases, and
increasing the priority of the first mask pattern based on the type of defect being an overlap defect, and as a difference between the margin of the first mask pattern and a reference value increases.
